(19) United States
(12) Patent Application Publication
(10) Pub. No.: US 2026/0166580 A1
(43) Pub. Date: Jun. 18, 2026

(54) CHAMBER ARRANGEMENTS, COATING SYSTEMS INCLUDING CHAMBER ARRANGEMENTS, AND METHODS OF COATING WORKPIECES IN CHAMBER ARRANGEMENTS AND COATING SYSTEMS

(71) Applicant: ASM IP Holding B.V., Almere (NL)

(72) Inventors: Robert Mecham, Chandler, AZ (US); Christopher Falcone, Chandler, AZ (US)

(21) Appl. No.: 19/417,631

(22) Filed: Dec. 12, 2025

Related U.S. Application Data
(60) Provisional application No. 63/735,018, filed on Dec. 17, 2024.

(51) Int. Cl. B05B 16/40; B05C 15/00

(52) U.S. Cl. CPC B05B 16/40; B05C 15/00

(57) ABSTRACT

A chamber arrangement includes an outer chamber and an inner chamber. The outer chamber has a hollow interior. The inner chamber is sized and dimensioned for placement within the interior of the outer chamber and may seat therein a workpiece to form a coating onto the workpiece, such as a substrate support structure for a semiconductor processing system. An electrical connector is seated in a wall of the outer chamber and fluidly separates the interior of the outer chamber from an external environment outside of the outer chamber to provide an electrical communication between the workpiece and the external environment outside of the outer chamber, such as for heating the workpiece and/or controlling temperature of the workpiece during the forming of the coating onto the workpiece. Coating systems and methods of forming coatings are also described.

### CROSS-REFERENCE TO RELATED APPLICATIONS

This application claims priority to U.S. Provisional Patent Application Ser. No. 63/735,018 filed Dec. 17, 2024 titled CHAMBER ARRANGEMENTS, COATING SYSTEMS INCLUDING CHAMBER ARRANGEMENTS, AND METHODS OF COATING WORKPIECES IN CHAMBER ARRANGEMENTS AND COATING SYSTEMS, the Disclosure of which is hereby incorporated by reference in its entirety.

The present disclosure generally relates to forming coatings onto workpieces, for example, ex-situ of assemblies or end items incorporating the workpieces.

### BACKGROUND OF THE DISCLOSURE

Material layers are commonly deposited and/or material removed from the substrates using reactors, such as during the fabrication of semiconductor devices. Deposition and/or removal may be accomplished by seating a substrate on a substrate support within a reactor and contacting the substrate with a precursor under conditions selected to cause a material layer to deposit and/or material be removed from the substrate. Once the substrate develops desired properties, for example a desired thickness and/or contour, the substrate may be removed from the reactor and sent on for further processing, as appropriate for the intended use of the substrate. In some processes the substrate support may be coated prior to seating the substrate on the substrate support, for example to facilitate development of desired properties in the surface of the substrate and/or the material layer deposited onto the substrate. Such coatings are typically deposited in-situ, i.e., with the substrate support arranged within the reactor, and prior to seating the substrate undergoing material layer deposition and/or material removal therefrom.

Such systems and methods have generally been considered suitable for their intended purpose. However, there remains a need for improved chamber arrangements, coating systems including chamber arrangements, and methods of forming coatings on workpieces. The present disclosure provides a solution to this need.

### SUMMARY OF THE DISCLOSURE

A chamber arrangement is provided. The chamber arrangement includes an outer chamber and an inner chamber. The outer chamber has a hollow interior. The inner chamber is sized and dimensioned for placement within the interior of the outer chamber and may seat therein a workpiece to deposit a material layer on the workpiece, such as a substrate support structure for a semiconductor processing system. An electrical connector is seated in a wall of the outer chamber and fluidly separates the interior of the outer chamber from an external environment outside of the outer chamber to provide an electrical communication between the workpiece and the external environment outside of the outer chamber, such as for heating the workpiece and/or controlling temperature of the workpiece during deposition of the coating onto the workpiece.

In addition to one or more of the features described above, or as an alternative, further examples of the chamber arrangement may include a lead arranged within the interior of the outer chamber. The electrical connector may be connected to the electrical connector to electrically couple the workpiece to the electrical connector.

In addition to one or more of the features described above, or as an alternative, further examples of the chamber arrangement may include that the electrical connector is one of a plurality of electrical connectors. The plurality of electrical connectors may be seated in the wall of the outer chamber.

In addition to one or more of the features described above, or as an alternative, further examples of the chamber arrangement may include that the lead is a first lead, and the chamber arrangement further includes one or more second lead. The one or more second lead may be configured to provide the electrical communication (e.g., power and/or signal) between the external environment and the workpiece, for example through the one or more electrical connector seated in the wall of the outer chamber.

In addition to one or more of the features described above, or as an alternative, further examples of the chamber arrangement may include that the one or more second lead is connected to the electrical connector.

In addition to one or more of the features described above, or as an alternative, further examples of the chamber arrangement may include that the electrical connector is a first electrical connector, and that the chamber arrangement includes one or more second electrical connector. The one or more second electrical connector may be seated in the wall of the outer chamber. The one or more second lead may be connected to the one or more second electrical connector.

In addition to one or more of the features described above, or as an alternative, further examples of the chamber arrangement may include that the inner chamber includes a base, a lid or cover, and a collar. The base may define a recess configured to receive therein a seating portion of a workpiece. The lid or cover may be seated on the base and define one or more aperture therethrough. The one or more aperture may in turn be configured to receive therethrough a stem portion of the workpiece, the stem portion of the workpiece extending from the seating portion of the workpiece. The collar may have a first end and an opposite second end. The first end of the collar may be seated on the lid or cover, extend about the one or more aperture, and protrude from the lid or cover in a direction opposite the base. The second end of the collar may be spaced apart from the first end of the collar. The second end of the collar may further be configured to extend about and support the workpiece such that seating portion of the workpiece depends from the collar within the recess of the base and the stem portion of the workpiece protrudes from the collar in a direction opposite the base of the inner chamber.

In addition to one or more of the features described above, or as an alternative, further examples of the chamber arrangement may include that the base of the inner chamber defines an aperture. A conduit may be fixed to an interior surface of the wall of the outer chamber. The conduit may be configured to provide fluid communication with the recess defined within the base of the inner chamber.

In addition to one or more of the features described above, or as an alternative, further examples of the chamber arrangement may include that the one or more workpiece aperture is a first workpiece aperture, that the conduit is a supply conduit, that the lid or cover of the inner chamber defines therethrough a second workpiece aperture, and that an exhaust conduit may be compressively fixed between the inner chamber and the wall of the outer chamber. The exhaust conduit may be fluidly coupled with the supply conduit through the recess defined within the base of the inner chamber.

In addition to one or more of the features described above, or as an alternative, further examples of the chamber arrangement may include a coating system precursor source and a coating system exhaust source. The coating system precursor source may be fluidly coupled to the recess defined within the base of the inner chamber by the supply conduit, the coating system exhaust source may be fluidly coupled to the recess defined within the base of the inner chamber by the exhaust conduit, and the recess defined within the base of the inner chamber may fluidly couple the coating system exhaust source to the coating system precursor source.

In addition to one or more of the features described above, or as an alternative, further examples of the chamber arrangement may include that the conduit and the base of the inner chamber define a leakage path or gap therebetween. The interior of the outer chamber may be fluidly coupled to the recess defined within the base of the inner chamber by the leakage path or gap defined between the conduit and the base of the inner chamber.

In addition to one or more of the features described above, or as an alternative, further examples of the chamber arrangement may include that the inner chamber is formed from stainless steel, aluminum, or titanium.

In addition to one or more of the features described above, or as an alternative, further examples of the chamber arrangement may include that the inner chamber is configured for forming a coating onto one or more workpiece.

In addition to one or more of the features described above, or as an alternative, further examples of the chamber arrangement may include one or more workpiece. The one or more workpiece may be suspended at least in part within the inner chamber. The one or more workpiece may be in electrical communication with the one or more electrical connector seated in the wall of the outer chamber.

In addition to one or more of the features described above, or as an alternative, further examples of the chamber arrangement may include the one or more workpiece includes a substrate support body. The substrate support body may include a heater element seated therein. The heater element may be electrically connected to the one or more electrical connector seated in the wall of the outer chamber. The substrate support body may include a temperature sensor seated therein. The temperature sensor may be electrically coupled to the one or more electrical connector seated in the wall of the outer chamber.

In addition to one or more of the features described above, or as an alternative, further examples of the chamber arrangement may include that the workpiece includes a coating. The coating may be a thermal barrier coating, a diamond-like carbon coating, an etch resistant coating, or an emissivity-matching coating.

In addition to one or more of the features described above, or as an alternative, further examples of the chamber arrangement may include that the workpiece is a medical device, a battery structure, or a gas turbine engine structure.

In addition to one or more of the features described above, or as an alternative, further examples may include that the workpiece is formed from a stainless steel material, a nickel-based material, or an aluminum-containing material. The workpiece may include a coating formed from a ceramic material such as a metal oxide, a metal fluoride, or a metal nitride.

A coating system is provided. The coating system includes a chamber arrangement as described above, a coating system precursor source, a coating system exhaust source, a coating system controller, and a workpiece. The inner chamber includes a base defining a recess therein. The workpiece is partially supported within the recess of the inner chamber and protrudes from the inner chamber and into the interior of the outer chamber. The coating system precursor source is fluidly coupled to the inner chamber, the coating system exhaust source is fluidly coupled to the inner chamber and therethrough to the coating system precursor source through the recess defined within the inner chamber, and the coating system controller is operatively connected to the coating system precursor source and disposed in communication with the workpiece. The coating system controller is further responsive to instructions recorded on a memory to form a coating onto the workpiece.

A method of forming a coating is provided. The method includes, at a chamber arrangement as described above, supporting a workpiece within the chamber arrangement; forming a coating onto the workpiece while supported within the chamber arrangement; removing the workpiece from the chamber arrangement; and installing the workpiece with the coating formed thereon in an assembly or end item.

In addition to one or more of the features described above, or as an alternative, further examples of the method may include providing the workpiece. The workpiece may be provided by forming a seating portion and a stem portion of a substrate support body from a metallic material or a ceramic material. The workpiece may be provided by removing the workpiece from an assembly or end item including the workpiece, such as a semiconductor processing system or a non-semiconductor processing system.

In addition to one or more of the features described above, or as an alternative, supporting the workpiece within the chamber arrangement may include support the workpiece within the inner chamber of the chamber arrangement, such as in an inverted orientation and/or suspended in (at least in part) within the inner chamber of the chamber arrangement. Supporting the workpiece within the chamber arrangement may include positioning the inner chamber with the workpiece supported therein within the outer chamber of the chamber arrangement.

In addition to one or more of the features described above, or as an alternative, forming the coating on the workpiece may include evacuating the recess within the inner chamber. Forming the coating may include evacuating the interior of the outer chamber. The interior of the outer chamber may be evacuated through the inner the chamber and/or through a gap or leakage path defined between a conduit and the inner chamber and/or the outer chamber, the conduit fluidly coupled to the coating system exhaust source.

A workpiece for a semiconductor processing system or a non-semiconductor processing system assembly or end item may include a coating formed using the coating method.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a coating system in accordance with the present disclosure, showing a coating being formed onto a workpiece ex-situ of an assembly or end item and the workpiece with the coating formed thereon thereafter being removed from the coating system and installed into the assembly or end item;

FIG. 2 is a longitudinal cross-sectional view of the chamber arrangement of FIG. 1 according to an example of the disclosure, showing an outer chamber with an inner chamber positioned within the outer chamber and supported on a supply conduit and an exhaust conduit;

FIG. 3 is a lateral cross-sectional view of the chamber arrangement of FIG. 1 according to an example of the disclosure, showing an electrical connector seated in a wall of the outer chamber and a lead coupling the electrical connector to the workpiece;

FIG. 4 is an exploded view of the inner chamber of the chamber arrangement of FIG. 1 according to an example of the disclosure, showing a collar and a clamping member employed to suspend the workpiece in the inner chamber exploded away from the workpiece; and

FIGS. 5-11 are a block diagram of a method of forming a coating onto a workpiece, showing operations of the method according to an illustrative and non-limiting example.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

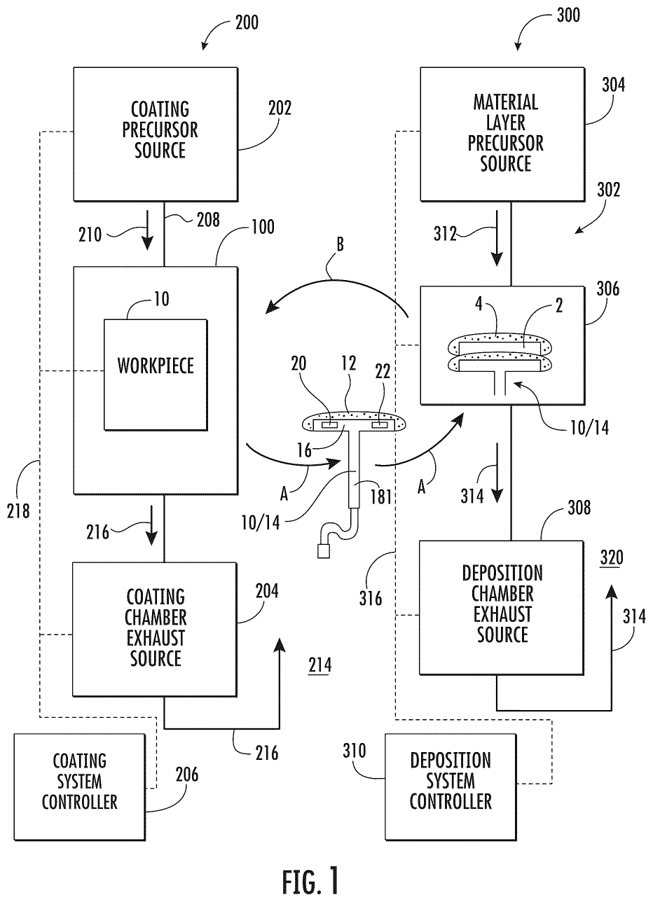

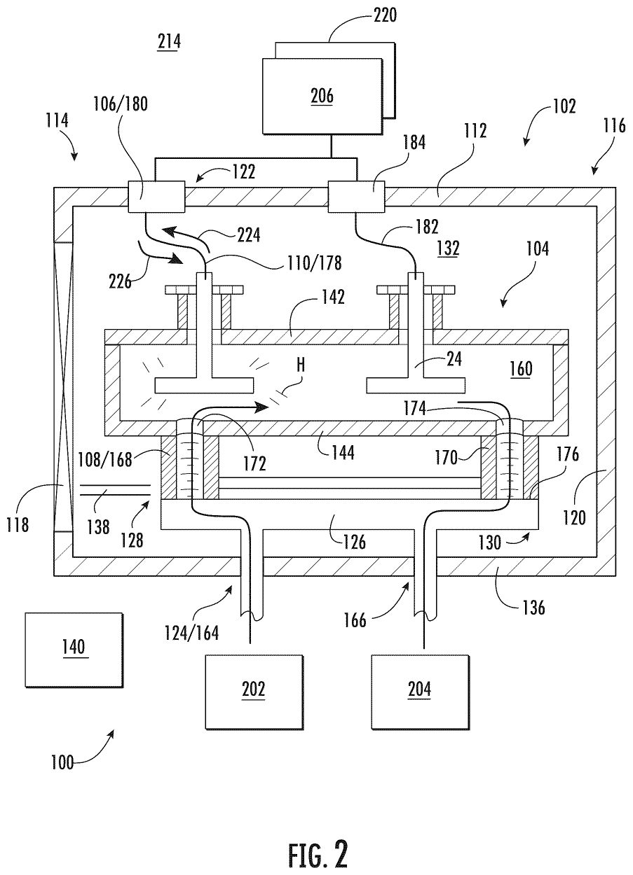

Reference will now be made to the drawings wherein like reference numerals identify similar structural features or aspects of the subject disclosure. For purposes of explanation and illustration, and not limitation, a partial view of a chamber arrangement for coating a workpiece prior to installing the workpiece in an assembly in accordance with the present disclosure is shown in FIG. 1 and is designated generally by reference character 100. Other examples of chamber arrangements, coating systems including chamber arrangements, and methods of coating workpieces using coating arrangements and coating systems in accordance with the present disclosure, or aspects thereof, are provided in FIGS. 2-11, as will be described. The systems and methods of the present disclosure may be used for coating workpieces ex-situ of assemblies intended to incorporate the coated workpieces, such as to form pre-coatings onto substrate support structures employed in semiconductor processing systems using atomic layer deposition techniques, though the present disclosure is not limited to any particular deposition technique or workpieces for semiconductor processing systems in general.

Referring to FIG. 1, a coating system 200 including the coating chamber arrangement 100 is shown according to an example of the disclosure. The coating system 200 is configured to form a coating 12 onto a workpiece 10, for example ex-situ of an assembly or end item into which the workpiece 10 (once coated) is to be installed, and in this respect may include a coating system precursor source 202, a coating system exhaust source 204, and a coating system controller 206. The coating system precursor source 202 is coupled to the coating chamber arrangement 100 by a coating precursor supply conduit 208, includes a coating precursor 210 (e.g., one or more of deionized water (H₂O), trimethylolethane (CH₃C(CH₂OH)₃), and/or ozone (O₃)), and is configured to communicate a flow of the coating precursor 210 to the coating chamber arrangement 100. The coating chamber arrangement 100 is configured to support therein the workpiece 10 during the forming of the coating 12 onto the workpiece 10 ex-situ of an assembly or end item into which the workpiece 10 is to be assembled, as shown with installation arrow A and refurbishment arrow B. The coating system exhaust source 204 is coupled to the coating chamber arrangement 100 by a coating chamber exhaust conduit 212, is in communication with an external environment 214 outside of the coating system 200 and is configured to communicate a flow of residual coating precursor and/or reaction products 216 to the external environment 214 outside of the coating system 200, for example using one or more of an abatement apparatus and a vacuum pump. It is contemplated that the coating system controller 206 be operably connected to one or more elements of the coating system 200, for example to the workpiece 10 while supported within the coating chamber arrangement 100 during forming of the coating 12 onto the workpiece 10, and in this respect may be operatively coupled to the coating chamber arrangement 100 and/or the workpiece 10 through a wired or wireless link 218 to the coating chamber arrangement 100. It is also contemplated that the coating system controller 206 be responsive to instructions recorded on a memory include in the coating system controller 206 to form the coating 12 onto the workpiece 10.

In certain examples the coating 12 may include (or consist of or consist essentially of) a ceramic material. In this respect it is contemplated that the coating 12 may include (or consist of or consist essentially of) a metal oxide, a metal fluoride, and/or metal nitride. Examples suitable metal oxides include aluminum oxide (Al₂O₃) or yttrium oxide (Y₂O₃). In further respect, it is also contemplated that the coating 12 may be a precoating, such as a precoating that may be employed to prepare the interior of a semiconductor processing for operation following replacement of a chamber component, such as a substrate support structure like a heater structure or a susceptor structure. It is also contemplated that the coating 12 may include (or consist of or consist essentially of) a thermal barrier coating, a diamond-like carbon coating, an etch resistant coating, or an emissivity-matching coating and remain within the scope of the present disclosure.

In certain examples the assembly or end item 300 into which the workpiece 10 is to be assembled may be a semiconductor processing system 302. In such examples the semiconductor processing system 302 may include a deposition precursor source 304, a deposition chamber arrangement 306, a deposition exhaust source 308, and a deposition system controller 310. The deposition precursor source 304 is configured to communicate a material layer precursor 312 to the deposition chamber arrangement 306. The deposition chamber arrangement 306 includes the workpiece 10 with the coating 12 formed thereon and is configured to contact a substrate 2 with the material layer precursor 312 under conditions selected to cause a material layer 4 to deposit onto the substrate 2. The deposition exhaust source 308 is in communication with an external environment 320 outside of the semiconductor processing system 302 and configured to communicate to the external environment 320 a flow of residual material layer precursor and/or reaction products 314 to the external environment 320 outside of the semiconductor processing system 302, for example through an abatement apparatus like a scrubber or a burn box. It is contemplated that the deposition system controller 310 be operatively associated with one or more element of the semiconductor processing system 302, for example through a wired or wireless link 316. Advantageously, forming the coating 12 onto the workpiece 10 may limit downtime associated with forming the coating 12 in-situ, e.g., onto the workpiece subsequent to installation in the deposition chamber arrangement 306, improving availability of the semiconductor processing system 302 and/or simplifying configuration of the semiconductor processing system 302, for example by avoiding the need to provision the semiconductor processing system 302 with a source of the coating precursor 210. As will be appreciated by those of skill in the art in view of the present disclosure, although shown and described herein as a semiconductor processing system configured for material layer deposition, it is to be understood that semiconductor processing systems configured for material removal (e.g., etchers) as well as semiconductor processing systems configured for both material layer deposition and material removal (e.g., configured for cyclic deposition and etch processes) may also benefit from the present disclosure. As will also be appreciated by those of skill in the art in view of the present disclosure, the assembly or end item 300 may be a non-semiconductor processing system assembly or end item (e.g., medical devices, battery structures, and gas turbine engine structures) and remain within the scope of the present disclosure.

In certain examples the workpiece 10 may be a chamber component for a semiconductor processing system, such as a semiconductor processing system employed for deposition of a material layer onto a substrate and/or removal of material from the substrate. In such examples the workpiece 10 may include a substrate support body 14 (e.g., a substrate support structure) having a seating portion 16 and a stem portion 18. The seating portion 16 of the substrate support body 14 may be configured to support thereon the substrate 2 and in this respect may be generally circular in shape. The stem portion 18 of the substrate support body 14 may extend from the seating portion 16 and in a direction opposite the substrate 2 (when seated thereon), may be configured to support the substrate support body 14 when installed in a material layer deposition and/or removal system, e.g., the semiconductor processing system 302, may include a cable hock with a connector, which may depend from the cable hock. In certain examples the substrate support body 14 (or the workpiece 10) may be formed from (or consist of or consist essentially of) a metallic material. Examples of suitable metallic materials include stainless steel materials, such as 316 stainless, and nickel-based alloys, such as alloy C22, or an aluminum-containing material like 6063 aluminum. In accordance with certain examples, the substrate support body 14 (or workpiece 10) may include the coating 12. In such examples the coating 12 may include (or consist of or consist essentially of) a ceramic material (e.g., aluminum oxide (Al₂O₃) or yttrium oxide (Y₂O₃) such as a metal oxide, a metal fluoride, or a metal nitride. It is also contemplated that the substrate support body 14 may be formed from a ceramic material. Examples of suitable ceramic materials include aluminum nitride (AlN) and ceramic composites, such as ceramic composites including aluminum oxide (Al₂O₃) and yttrium oxide (Y₂O₃) by way of non-limiting example. In such examples the coating 12 may encapsulate a wetted portion of the substrate support body 14, for example the limit (or prevent entirely) particulate and/or material diffused from the substrate support body 14 from entering a process volume within the semiconductor processing system. As will be appreciated by those of skill in the art in view of the present disclosure, the workpiece 10 may include another type of chamber component body, such as a showerhead body or gas line body, and remain within the scope of the present disclosure.

In certain examples the workpiece 10 may include one or more of a heater element 20 and one or more temperature sensor 22. The one or more the heater element 20 in such examples may be configured to heat the workpiece 10 to a predetermined coating temperature, for example during the ex-situ forming of the coating 12 onto the workpiece 10, and in this respect may be seated (e.g., fixed) within the workpiece 10, such as within the seating portion 16 of the substrate support body 14. The one or more temperature sensor 22 in such examples may be configured to generate a temperature signal containing information indicative of temperature of the workpiece 10, for example during the ex-situ forming of the coating onto the workpiece 10 to control temperature of the workpiece 10, and in this respect may be seated (e.g., fixed) within the workpiece 10, such as within the seating portion 16 of the substrate support body 14. As will be appreciated by those of skill in the art in view of the present disclosure, the one or more heater element 20 and the one or more temperature sensor 22 may also configured to heat the substrate support body 14 and control temperature of the substrate support body 14, respectively, during deposition of a material layer 4 onto a substrate 2 while seated on the substrate support body 14. As will also be appreciated by those of skill in the art in view of the present disclosure, along shown and described herein as including a singular heater element 20 and a singular temperature sensor 22, it is to be understood and appreciated that the workpiece 10 may include additional heater elements and/or temperature sensors and remain within the scope of the present disclosure.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates may be made from semiconductor materials, including, for example, silicon (Si), silicon germanium (SiGe), silicon oxide (SiO₂), gallium arsenide (GaAs), gallium nitride (GaN) and silicon carbide (SiC). As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

With reference to FIGS. 2-4, the coating chamber arrangement 100 is shown according to an example of the disclosure. As shown in FIG. 2, the coating chamber arrangement 100 generally includes an outer chamber 102 and an inner chamber 104. In the illustrated example the coating chamber arrangement 100 also includes an electrical connector 106, one or more fluid conduit 108, and one or more lead 110. Although shown and described herein as including certain elements, it is to be understood and appreciated that the coating chamber arrangement 100 may include additional elements and/or exclude certain elements shown and described herein and remain within the scope of the present disclosure.

The outer chamber 102 is configured to receive therein the inner chamber 104 for positioning within the outer chamber 102. In this respect it is contemplated that the outer chamber 102 may have a wall 112 with a generally cylindrical shape extending longitudinally between a first end 114 and a second end 116 of the outer chamber 102. In the illustrated example a door 118 is pivotably supported at the first end 114 of the outer chamber 102 and that an end wall 120 be sealably fixed to the second end 116 of the outer chamber 102. In the illustrated example the wall 112 of the outer chamber 102 further defines therethrough one or more electrical penetration 122 and one or more fluid penetration 124. It is contemplated that the one or more electrical connector 106 be seated in the one or more electrical penetration 122, the electrical connector 106 fluidly separating an interior 132 of the outer chamber 102 from the external environment 214 outside of the coating chamber arrangement 100, the electrical connector 106 providing electrical communication between the workpiece 10 and a device (e.g., the coating system controller 206 and/or the power source 220) located in the external environment 214 outside of the coating system 200. It is also contemplated that a manifold 126 may be seated within the interior 132 of the outer chamber 102, the manifold 126 in turn fluidly communicating with the coating system precursor source 202 and the coating system exhaust source 204 through the one or more fluid penetration 124, the manifold in turn having a manifold supply port 128 and a manifold exhaust port 130.

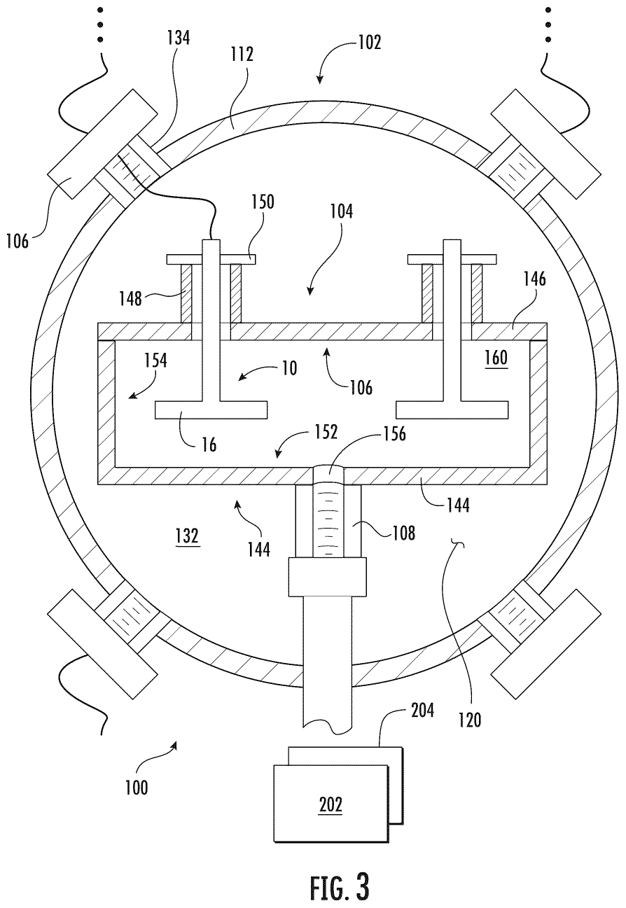

Referring to FIG. 3, it is contemplated that the outer chamber 102 of the coating chamber arrangement 100 may have one or more lug portion 134 protruding from an outer surface of the wall 112 of the outer chamber 102. In such examples the one or more electrical connector may be supported on the one or more lug portion 134, the one or more lug portion 134 in turn simplifying support of the one or more electrical connector 106 by providing a substantially planar seating flange for the one or more electrical connector 106. In the illustrated example the outer chamber 102 defines therethrough four (4) electrical penetrations distributed about a periphery of the outer chamber 102, has four (4) lug portions each protruding from the wall 112 of the outer chamber 102, and includes four (4) electrical connectors each seated on a respective one of the four (4) lug portions. As will be appreciated by those of skill in the art in view of the present disclosure, the outer chamber 102 may have fewer or additional electrical connectors (and associated electrical penetrations and lug portions) than shown and described herein in other examples, as well as electrical connectors supported at other locations on the wall 112 and remain within the scope of the present disclosure.

With continuing reference to FIG. 2, the outer chamber 102 of the coating chamber arrangement 100 may be formed from an outer chamber metallic material 136. In certain examples the outer chamber metallic material 136 may include stainless steel, such as 316 stainless. As will be appreciated by those of skill in the art in view of the present disclosure, forming the outer chamber 102 from stainless steel may impart corrosion resistance to the outer chamber 102 of the coating chamber arrangement 100. In accordance with certain examples, the outer chamber metallic material 136 may include carbon steel or an aluminum alloy, such as 6064 aluminum. As will also be appreciated by those of skill in the art in view of the present disclosure, forming the outer chamber 102 from carbon steel or aluminum alloy may simplify fabrication of the outer chamber 102, limiting cost of the coating chamber arrangement 100. Advantageously, forming the outer chamber with a generally cylindrical shape may further simplify fabrication of the outer chamber 102 in applications wherein the interior 132 of the outer chamber 102 is evacuated, for example by limiting wall thickness required for a given reduced pressure within the interior 132 of the outer chamber 102.

It is contemplated that one or more longitudinal rail 138 may be arranged within the interior 132 of the outer chamber 102. The one or more longitudinal rail 138 may configured to facilitate positioning of the inner chamber 104 within the interior 132 of the outer chamber 102. In this respect the one or more longitudinal rail 138 may extend from the door 118 toward the second end 116 of the outer chamber 102, include two longitudinal rails each laterally offset from the manifold 126, and be configured to receive a cart or carriage 140 configured to carry to the inner chamber 104 into and out of the interior 132 of the interior 132 of the outer chamber 102. As will be appreciated by those of skill in the art in view of the present disclosure, inclusion of the one or more longitudinal rail 138 within the outer chamber 102 may simplify use of the coating chamber arrangement 100, for example by enabling the formation of the coating 12 (shown in FIG. 1) on relatively large workpieces and/or large numbers of workpieces and/or the loading and unloading of the relatively large workpieces (or large number of workpieces) using a single technician, limiting cost associated with forming the coating 12 onto the workpiece 10.

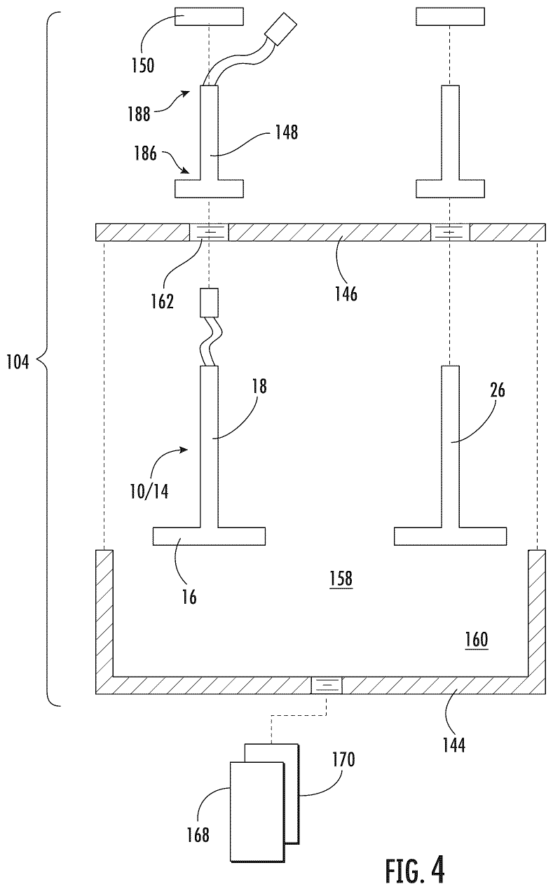

Referring once again to FIG. 3, it is contemplated that the inner chamber 104 be configured to be positioned within the outer chamber 102 while supporting the workpiece 10 for forming the coating 12 (shown in FIG. 1). In this respect the inner chamber 104 may be sized and dimensioned for positioning within the interior 132 of the outer chamber 102 and in the illustrated example the inner chamber 104 includes a base 144, a lid or cover 146, one or more collar 148, and one or more clamp member 150. The base 144 has a floor portion 152 and a sidewall portion 154 extending peripherally about the floor portion 152. It is contemplated that the floor portion 152 of the base 144 may be substantially planar in contour and be configured to fluidly couple the inner chamber 104 to the coating system precursor source 202 (shown in FIG. 1) and the coating system exhaust source 204 (shown in FIG. 1), for example through the one or more fluid conduit 108, and in this respect defines one or more inner chamber fluid port 156. The sidewall portion 154 extends about the floor portion 152 of the base 144 and from the floor portion 152 in a direction opposite the inner chamber fluid port 156 and is configure to seat there on the lid or cover 146. It is contemplated that the base 144 have an open top 158 (shown in FIG. 4) corresponding to the lid or cover 146 and defining a recess 160 therein. It is contemplated that the recess 160 in turn be configured to house therein at least a portion of the workpiece 10, for example the seating portion 16 of the substrate support body 14, and that the one or more inner chamber fluid port 156 be configured to contact the workpiece 10 with a flow (or charge) of the coating precursor 210 (shown in FIG. 1) introduced into the recess 160 therethrough to form the coating 12 (shown in FIG. 1) onto the workpiece 10, for example onto at least the seating portion 16 of the substrate support body 14 suspended within the recess 160. In this respect it is contemplated that the workpiece 10 may be partially supported within the recess 160 of the inner chamber 104 and protrude from the inner chamber 104 into the interior 132 of the outer chamber 102. Advantageously, this enables electrically coupling the heater element 20 and/or the temperature sensor 22 to the coating system controller 206 and/or the power source 220 using the one or more electrical connector 106.

As shown in FIG. 4, the lid or cover 146 may be generally planar in contour defines one or more workpiece aperture 162 therethrough. The one or more workpiece aperture 162 is configured to receive therethrough a portion of the workpiece 10, for example the stem portion 18 of the workpiece 10, and in this respect provides fluid communication with the recess 160 when the workpiece 10 is supported (at least in part) in the recess 160. It is contemplated that the one or more collar 148 be seated on the lid or cover 146 and extend about the one or more workpiece aperture 162, for example with a plurality of fasteners extending through a flange portion of the one more collar 148 and seated in a fastener pattern extending about the one or more workpiece aperture 162, and that a portion of the workpiece 10 may further extend through the one or more collar 148, such as the stem portion 18 of the substrate support body 14. In this respect it is contemplated that the collar 148 may have a first end 186 and an opposite a second end 188, that the first end 186 may be seated on the lid or cover146 and extend about the one or more workpiece aperture 162, and that the second end 188 of the collar 148 may be spaced apart from the first end 186 of the collar 148. The second end 188 of the collar 148 may be further configured to extend about and support, in cooperation with the clamp member 150, the workpiece 10 within the inner chamber 104 such that the stem portion 18 of the workpiece 10 protrudes from the second end 188 of the collar 148 and into the interior 132 of the outer chamber 102.

It is further contemplated that the one or more clamp member 150 may be fixed to an end of the collar 148 opposite the lid or cover 146, the clamp member 150 may further extend about the workpiece (e.g., the stem portion 18 of the substrate support body 14), and that the clamp member 150 may couple the workpiece to the inner chamber 104 via the collar 148 such that the workpiece 10 dangles from the end of the collar 148 and within the recess 160 defined with the base 144 of the inner chamber 104. In certain examples the workpiece may protrude from the clamp member 150 and into the interior 132 (shown in FIG. 2) of the outer chamber 102 (shown in FIG. 2) external to the inner chamber 104, for example such that a cable hock and cable connector of the workpiece 10 are accessible when the inner chamber 104 is positioned with the outer chamber 102 of the coating chamber arrangement 100 (shown in FIG. 1).

With continuing reference to FIG. 2, it is contemplated that recess 160 defined within the base 144 of the inner chamber 104 fluidly couple the coating system precursor source 202 to the coating system exhaust source 204. In this respect the one or more fluid penetration 124 may include a supply penetration 164 and an exhaust penetration 166. The supply penetration 164 may be coupled to the coating system precursor source 202 by the coating precursor supply conduit 208 (shown in FIG. 1), may in turn fluidly couple the coating precursor supply conduit 208 to the manifold 126, and the manifold 126 may further fluidly couple the coating system precursor source 202 to the recess 160 through the one or more fluid conduit 108. The exhaust penetration 166 may be coupled to the coating system exhaust source 204 by the coating chamber exhaust conduit 212 (shown in FIG. 1) and may in turn fluidly couple the recess 160 to the coating system exhaust source 204 through the one or more fluid conduit 108 and the manifold 126. In the illustrated example the one or more fluid conduit 108 includes a supply conduit 168 and an exhaust conduit 170, the one or more inner chamber fluid port 156 includes an inner chamber supply port 172 and the inner chamber exhaust port 174, the supply conduit 168 fluidly couples the manifold 126 to the recess 160 through the inner chamber supply port 172, and the inner chamber exhaust port 174 fluidly couples the recess 160 to the manifold 126 through the exhaust conduit 170. As will be appreciated by those of skill in the art in view of the present disclosure, the manifold 126 may define therein fluidly separate source and exhaust circuits fluidly coupling the supply conduit 168 and the exhaust conduit 170 in fluid communication with the supply penetration 164 and the exhaust penetration 166, respectively.

In certain examples the supply conduit 168 and the exhaust conduit 170 may support the inner chamber 104 within the interior 132 of the outer chamber 102. In this respect it is contemplated the supply conduit 168 may be compressively fixed between the base 144 of the inner chamber 104 and the manifold 126 at a location whereat the supply conduit 168 fluidly couples the manifold supply port 128 (and therethrough the supply penetration 164) to the inner chamber supply port 172, and that the exhaust conduit 170 may be compressively fixed between the base 144 of the inner chamber 104 and manifold 126 at a location whereat the exhaust conduit 170 fluidly couples the inner chamber exhaust port 174 to the manifold exhaust port 130 (and therethrough the exhaust penetration 166). In further respect, either (or both) the supply conduit 168 and the exhaust conduit 170 may be loose fit (e.g., leaky) between the manifold 126 and the inner chamber 104, for example without a sealing member or gasket therebetween, such that a leakage path or gap 176 is defined between the coating system exhaust source 204 (shown in FIG. 1) during forming of the coating 12 onto the workpiece 10. Advantageously, supporting the inner chamber 104 on the supply conduit 168 and the exhaust conduit 170 such that the supply conduit 168 and the exhaust conduit 170 are compressively fixed between the inner chamber 104 and the manifold 126 may simplify operation of the coating chamber arrangement 100, for example by avoiding the need for clamps and/or fasteners, enabling the inner chamber 104 to be removed from within the outer chamber 102 without the need for cooling the inner chamber 104 subsequent to forming the coating 12 onto the workpiece 10.

In certain examples the inner chamber metallic material 142 may be formed from the same material as outer chamber 102. For example, the inner chamber metallic material 142 may include a stainless-steel material, such as 316 stainless by way of non-limiting example. The inner chamber metallic material 142 may include a carbon steel material or an aluminum-containing material, such as 6064 aluminum by way of non-limiting example. It is also contemplated that the inner chamber metallic material 142 may include a nickel-based material, such as Hastelloy, or titanium. In accordance with certain examples, the inner chamber 104 may be formed from a material differing from that forming the outer chamber 102. In this respect it is contemplated that the outer chamber metallic material 136 forming the outer chamber 102 may include (or consist of or consist essentially of) a stainless-steel material, and the inner chamber metallic material 142 forming the inner chamber 104 may include (or consist of or consist essentially of) an aluminum-containing material. As will be appreciated by those of skill in the art in view of the present disclosure, forming the inner chamber 104 from an aluminum-containing material may simplify fabrication of the inner chamber 104 and/or simplify positioning the inner chamber 104 within the outer chamber 102. For example, employment of certain relatively light-weight aluminum alloys may enable the inner chamber 104 to be positioned within the outer chamber 102 by a single technician, limiting costs otherwise associated with forming the coating 12 onto the workpiece 10 using the coating chamber arrangement 100.

Referring again to FIG. 3, it is contemplated that the one or more lead 110 electrically couple the workpiece 10 to the one or more electrical connector 106 and therethrough to a device located in the external environment 214 outside of the coating chamber arrangement 100, for example the coating system controller 206 (shown in FIG. 1) or the power source 220 (shown in FIG. 2). In this respect the one or more lead 110 is arranged within the interior 132 of the outer chamber 102, is connected at a first end to the workpiece 10, and is connected at a second end to the one or more electrical connector 106. In certain examples the one or more lead 110 may electrically couple a heater element arranged within the workpiece 10, e.g., the one or more heater element 20 (shown in FIG. 1), to the one or more electrical connector 106 and therethrough to a power source arranged in the external environment 214 outside of the coating chamber arrangement 100. In accordance with certain examples, the one or more lead 110 may electrically couple a temperature sensor arranged within the workpiece 10, e.g., the one or more temperature sensor 22 (shown in FIG. 1), to the one or more electrical connector 106 and therethrough to a controller arranged in the external environment 214 outside of the coating chamber arrangement 100 and operatively associated with the power source. In the illustrated example the one or more lead 110 includes a first lead 178 coupling the workpiece 10 to a first electrical connector 180 seated in the wall 112 of the outer chamber 102 and a second lead 182 coupling the workpiece 10 to a second electrical connector 184 seated in the wall 112 of the outer chamber 102. As will be appreciated by those of skill in the art in view of the present disclosure, the coating chamber arrangement 100 may have fewer leads of additional leads in certain examples and remain within the scope of the present disclosure.

In certain examples the coating chamber arrangement 100 may be configured to support a plurality of workpieces during the forming of coatings onto the workpieces. In this respect it is contemplated that the workpiece 10 may be a first workpiece 10 and one or more second workpiece 24. The one or more second workpiece 24 may be similar to the first workpiece 10 and additionally be supported (e.g., suspended so as to dangle) in the inner chamber 104, for example at a location offset from the first workpiece 10. In certain examples the inner chamber 104 may be configured to support four (4) workpieces. As will be appreciated by those of skill in the art in view of the present disclosure, this enables coincident formation of coatings on each of the substrate support structures employed in a single quad chamber module (QCM) semiconductor processing system, which can simplify the service and/or maintenance of semiconductor processing systems including QCMs.

In certain examples a dummy workpiece 26 may be supported in the inner chamber 104 during the forming of the coating 12 onto the workpiece. In such examples the dummy workpiece may conform in fit to the workpiece 10, for example having similar shape and surface texture. As will be appreciated by those of skill in the art in view of the present disclosure, this may simplify operation of the coating system 200 (shown in FIG. 1), for example by limiting flow variation otherwise possible when operating the coating system 200 at less than full capacity (e.g., with a short load). In accordance with certain examples, the dummy workpiece 26 may substantially match the workpiece 10 in weight and/or center-of-gravity. As will also be appreciated by those of skill in the art in view of the present disclosure, this may also simplify operation of the coating system 200, for example by enabling the inner chamber 104 to be balanced within the outer chamber 102 when operating the coating system 200 at less than full capacity (e.g., with a short load).

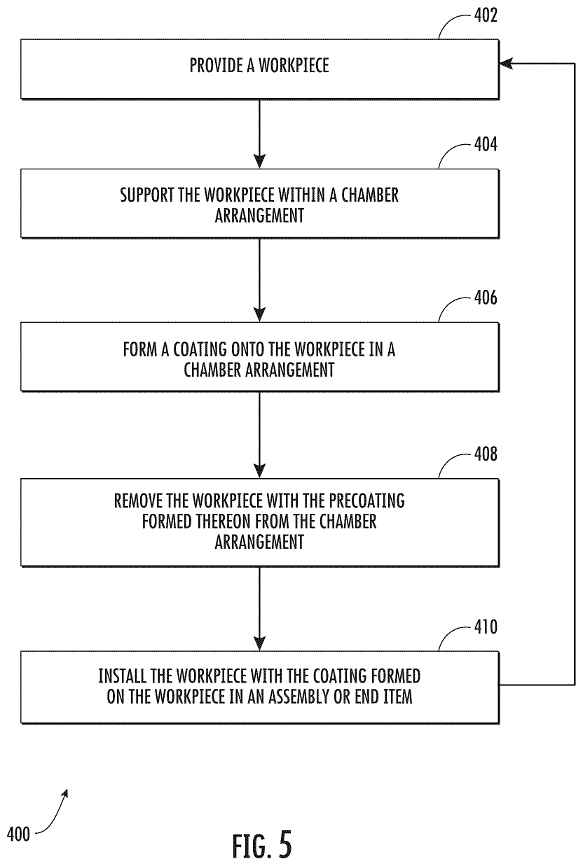

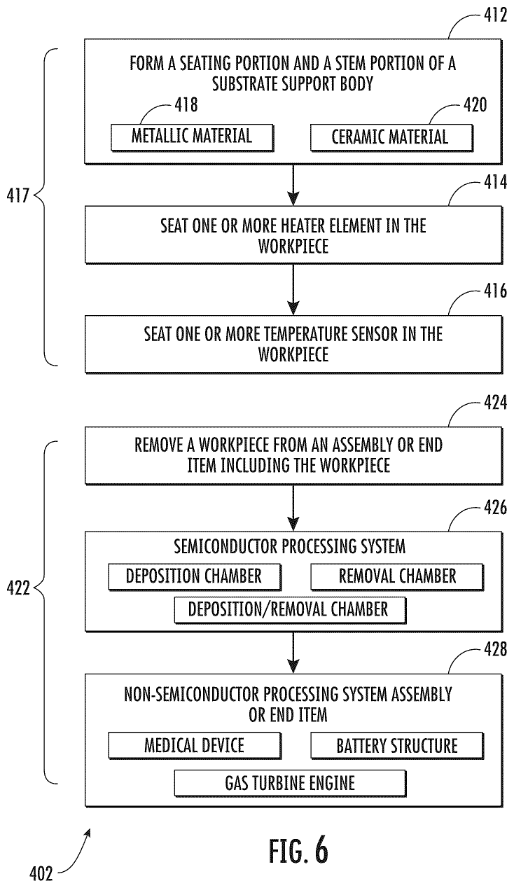

With reference to FIGS. 5 and 6, a method 400 of forming a coating onto a workpiece, for example ex-situ of an assembly or end item into which the workpiece with the coating formed thereon is to be installed, e.g., the coating 12 (shown in FIG. 1) onto the workpiece 10 (shown in FIG. 1), is shown according to an example of the disclosure. In the illustrated example the method 400 includes providing the workpiece and supporting the workpiece within a chamber arrangement, e.g., the coating chamber arrangement 100 (shown in FIG. 1), as shown with box 402 and box 404. In the illustrated example the method 400 also include forming the coating onto the workpiece while supported within the chamber arrangement, as shown with box 406; removing the workpiece with the coating formed onto the workpiece from the chamber arrangement, as shown with box 408; and installing the workpiece with the coating formed thereon in an assembly or end item, e.g., the assembly or end item 300 (shown in FIG. 1), such that the assembly or end item includes the workpiece with the coating formed thereon ex-situ of the assembly or end item, as shown with box 410. Although shown and described herein as including certain operations it is to be understood and appreciated that the method 400 may include additional operations and/or exclude certain operations shown and described here and remain with the scope of the present disclosure.

As shown in FIG. 6, providing 402 the workpiece may include forming a new-build workpiece, as shown with bracket 417. In this respect it is contemplated that a seating portion and a stem portion of a substrate support body may be formed from a workpiece material, e.g., the seating portion 16 (shown in FIG. 1) and the stem portion 18 (shown in FIG. 1) of the substrate support body 14 (shown in FIG. 1), as shown with box 412. Providing 402 the workpiece may include seating one or more heater element and/or one or more temperature sensor within the workpiece material forming workpiece, e.g., the one or more heater element 20 (shown in FIG. 1) and/or the one or more temperature sensor 22 (shown in FIG. 1), as shown with box 414 and box 416, respectively. In certain example the workpiece may be formed from a metallic material, such as stainless steel or a nickel-based material, as shown with box 418. In accordance with certain examples, the workpiece may be formed from a ceramic material, such as aluminum nitride (AlN) by way of non-limiting example, as shown with box 420.

In certain examples providing 402 the workpiece may include removing the workpiece from an assembly or end item including the workpiece, e.g., the assembly or end item 300 (shown in FIG. 1), as shown with bracket 422. In this respect it is contemplated that the workpiece may be provided by first removing the workpiece from the assembly or end item, removing a previously formed coating from the workpiece, and thereafter forming the coating onto the workpiece, as also shown with box 424. In certain examples the workpiece may be a semiconductor processing system workpiece upon which the coating is to be formed, such as a substrate support structure (e.g., a heater structure or a susceptor structure), as shown with box 426. In this respect it is contemplated that the workpiece may be removed from a material layer deposition chamber, a material removal chamber, or a chamber configured for both material layer deposition and material removal, as also shown with box 426. In accordance with certain examples, the workpiece upon which the coating is to be formed may be removed from a non-semiconductor processing system assembly or end item, as shown with box 428. Non-limiting examples of non-semiconductor processing system workpieces include medical devices, battery structures, and gas turbine engine structures, as shown also shown with box 428.

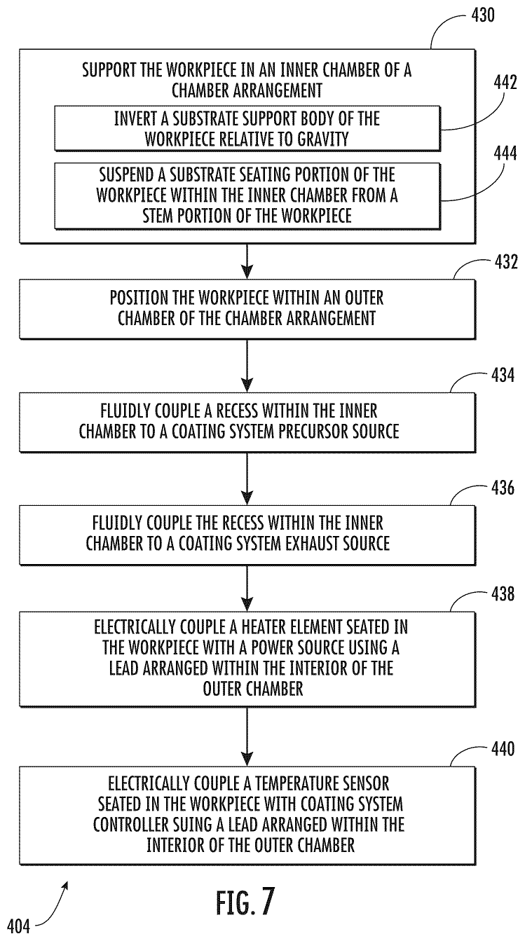

As shown in FIG. 7, supporting 404 the workpiece within the chamber arrangement may include supporting the workpiece within an inner chamber of the chamber arrangement, e.g., the inner chamber 104 (shown in FIG. 2), as shown with box 430. Supporting 404 the workpiece within the chamber arrangement may include positioning the inner chamber with the workpiece supported therein within an outer chamber of the chamber arrangement, e.g., the outer chamber 102 (shown in FIG. 2), as shown with box 432. Supporting 404 the workpiece within the chamber arrangement may include fluidly coupling a recess defined within the inner chamber and containing (at least in part) a portion of the workpiece to a coating precursor source, e.g., the coating system precursor source 202 (shown in FIG. 1), as shown with box 434. Supporting 404 the workpiece within the chamber arrangement may include fluidly coupling the recess and therethrough the coating precursor source to a coating system exhaust source, e.g., the coating system exhaust source 204 (shown in FIG. 1), as shown with box 436.

In certain examples supporting 404 the workpiece within the chamber arrangement may include supporting the inner chamber with the workpiece supported therein on a cart or carriage, e.g., the cart or carriage 140 (shown in FIG. 1), as also shown with box 430. It is contemplated that the cart or carriage with the inner chamber supported thereon may be advanced in the outer chamber via one or more longitudinal rail arranged within the outer chamber, e.g., the one or more longitudinal rail 138 (shown in FIG. 2), as further shown with box 430. The inner chamber may be registered within the outer chamber relative to a manifold, e.g., the manifold 126 (shown in FIG. 2), and that the inner chamber be lowered within the outer chamber onto the manifold that the inner chamber is supported on one or more fluid conduit, e.g., the one or more fluid conduit 108 (shown in FIG. 2), as additionally shown with box 430. In this respect it is contemplated that an inlet fluid conduit and an exhaust fluid conduit may support the inner chamber within the outer chamber, e.g., the supply conduit 168 (shown in FIG. 2) and the exhaust conduit 170 (shown in FIG. 2), the inlet fluid conduit and the exhaust fluid conduit both compressively fixed between the inner chamber and the manifold within the outer chamber n certain examples of the disclosure.

In certain examples supporting 404 the workpiece within the chamber arrangement may include electrically coupling a heater element seated within the workpiece to an electrical connector and therethrough to an external power source using a lead arranged within the interior of the outer chamber, e.g., electrically coupling the one or more heater element 20 (shown in FIG. 1) to the power source 220 (shown in FIG. 2) through the first electrical connector 180 (shown in FIG. 2) using the first lead 178 (shown in FIG. 2) to receive a flow of electrical power 226 (shown in FIG. 2), as shown with box 438. Supporting 404 the workpiece within the chamber arrangement may include electrically coupling a temperature sensor seated within the workpiece to an electrical connector and therethrough to a coating system controller using a lead arranged within an interior of the outer chamber, e.g., electrically coupling the one or more temperature sensor 22 (shown in FIG. 1) to the coating system controller 206 (shown in FIG. 1) using the second lead 182 (shown in FIG. 3) through the second electrical connector 184 (shown in FIG. 2), as shown with box 440.

In certain examples supporting 404 the workpiece within the inner chamber may include inverting the workpiece relative to gravity, as shown with box 442. The inverted workpiece may be suspended within the inner chamber of the chamber arrangement, for example such that the seating portion of the substrate support body is disposed within the recess defined within the inner chamber, as shown with box 444. The seating portion of the substrate support body may dangle within the recess from the stem portion of the substrate support body, for example from a clamping member and a collar of the inner chamber, e.g., the clamp member 150 (shown in FIG. 1) and the collar 148 (shown in FIG. 2), as also shown with box 444.

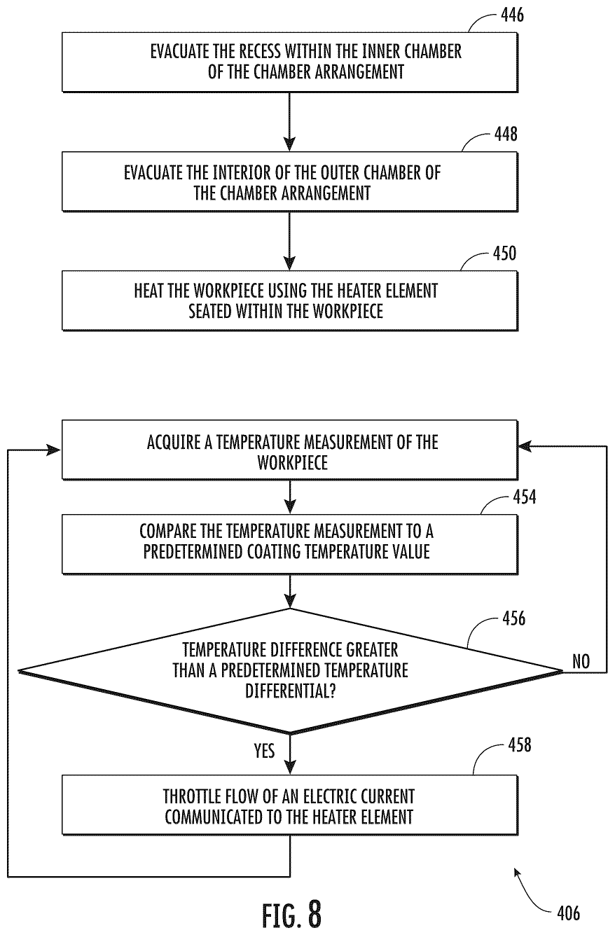

As shown in FIG. 8, forming 406 the coating onto the workpiece may include evacuating the recess (e.g., an interior of the inner chamber) containing (at least in part) the workpiece using the coating system exhaust source, as shown with box 446. Forming 406 the coating onto the workpiece may include evacuating the interior of the outer chamber using the coating system exhaust source, for example a portion of the interior of the outer chamber outside of the inner chamber when the inner chamber is supported within the outer chamber of the chamber arrangement, as shown with box 448. Forming 406 the coating onto the workpiece may include heating the workpiece using the heater element seated within the workpiece, for example without communicating heat into the workpiece through either (or both) the outer chamber and the inner chamber, as shown with box 450. Heating 450 the workpiece may further include controlling temperature of the workpiece using a temperature measurement acquired using the temperature sensor seated within the workpiece, e.g., the temperature measurement 224 (shown in FIG. 2), and in this respect the temperature measurement may be compared to a predetermined temperature valve and power applied to the heater element throttled when the acquired temperature measurement differs from the predetermined coating deposition temperature measurement by more than a predetermined temperature differential value, as shown with boxes 452-458.

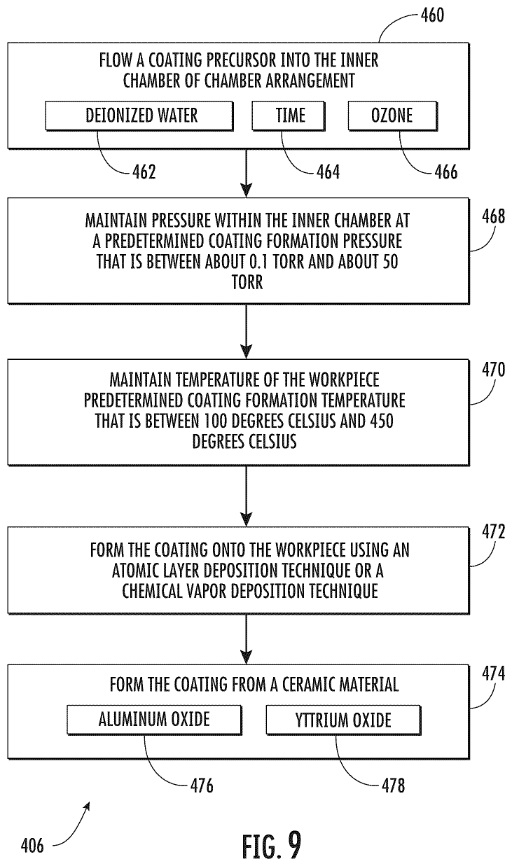

As shown in FIG. 9, forming 406 the coating onto the workpiece may include flowing one or more coating precursor into the recess and contacting the workpiece with the one or more coating precursor, e.g., the coating precursor 210 (shown in FIG. 1), under conditions selected to cause the coating to form onto the workpiece, as shown with box 460. In this respect it is contemplated that the workpiece may be contacted with one or more of deionized water (H₂O), trimethylolethane (CH₃C(CH₂OH)₃), and/or ozone (O₃), as shown with boxes 462-466; that pressure within the inner chamber of the chamber arrangement may be maintained at a predetermined coating formation pressure that is between about 0.1 Torr and about 50 Torr during forming of the coating onto the workpiece, as shown with box 468, and that the workpiece be may be maintained at a predetermined coating forming temperature that is between about 100 degrees Celsius and about 450 degrees Celsius during forming of the coating onto the workpiece, as shown with box 470. In further respect, the coating may be formed using an atomic layer deposition technique or a chemical vapor deposition technique, as shown with box 472. It is contemplated that the coating formed onto the workpiece may include (or consist of or consist essentially of) a ceramic material, as shown with box 474, such as aluminum oxide (Al₂O₃) or an yttrium-containing ceramic material such as yttrium oxide (Y₂O₃), as shown with box 476 and 478.

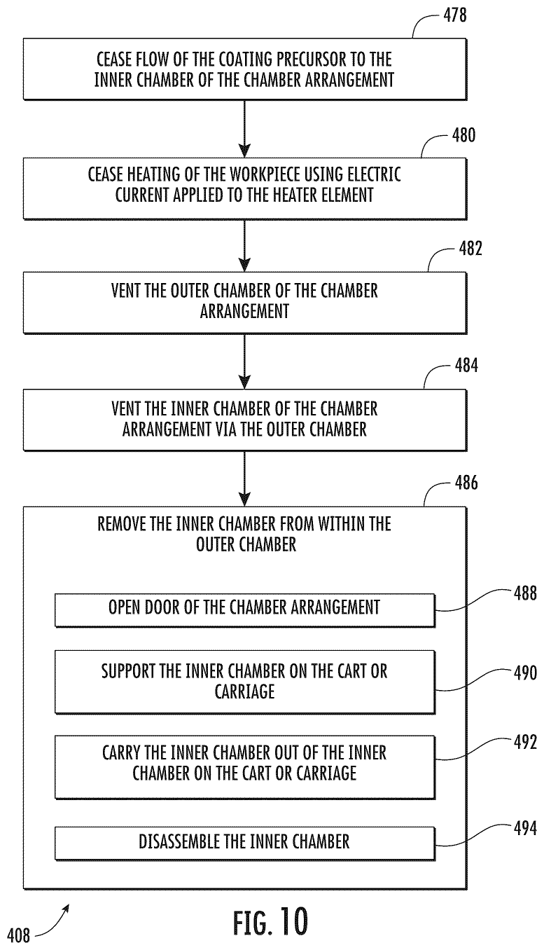

As shown in FIG. 10, removing 408 the workpiece from the chamber arrangement may include ceasing flow of the coating precursor into the inner chamber from the coating system precursor source, as shown with box 480. Removing 408 the workpiece from the chamber arrangement may include ceasing heating of the workpiece, for example by ceasing flow of electric current to the one or more heater element seated in the workpiece, as shown with box 482. It is contemplated that the interior of the outer chamber may be vented such that pressure within the interior of the outer chamber is substantially equivalent to pressure in the external environment outside of the chamber arrangement, as shown with box 484. It is also contemplated that the recess within the inner chamber may be vented such that pressure within the recess is substantially equivalent to pressure in the external environment outside of the chamber arrangement, as shown with box 486. In certain examples venting of the inner chamber may be accomplished through the exhaust fluid conduit, as also shown with box 486. In accordance with certain examples, the venting of the interior of the outer chamber may be accomplished using the exhaust fluid conduit, for example using one or more leakage path defined between the exhaust fluid conduit and inner chamber and/or between the exhaust fluid conduit and the outer chamber, as also shown with box 484. It is contemplated that, once the interior of the outer chamber is vented, the inner chamber (carrying the workpiece) may be removed from the outer chamber, as shown with box 486.

Removal 486 of the inner chamber from the outer chamber may include opening a door pivotably supported relative to the outer chamber, e.g., the door 118 (shown in FIG. 2), as shown with box 488. The inner chamber may be supported on the cart or carriage and inner chamber lifted, for example such that the inlet fluid conduit and the exhaust fluid conduit are no longer compressively fixed between the inner chamber and the outer chamber, as shown with box 490. The cart or carriage carrying the inner chamber may thereafter be withdrawn from within the interior of the outer chamber, for example by sliding the cart or carriage along the one or more longitudinal rail arranged within the outer chamber of the chamber arrangement, as shown with box 492. It is contemplated that the inner chamber may thereafter be disassembled to remove the workpiece from the inner chamber, for example by removing the lid of the inner chamber and separating the clamping member from the workpiece such that workpiece may be withdrawn from the collar of the inner chamber, as shown with box 494.

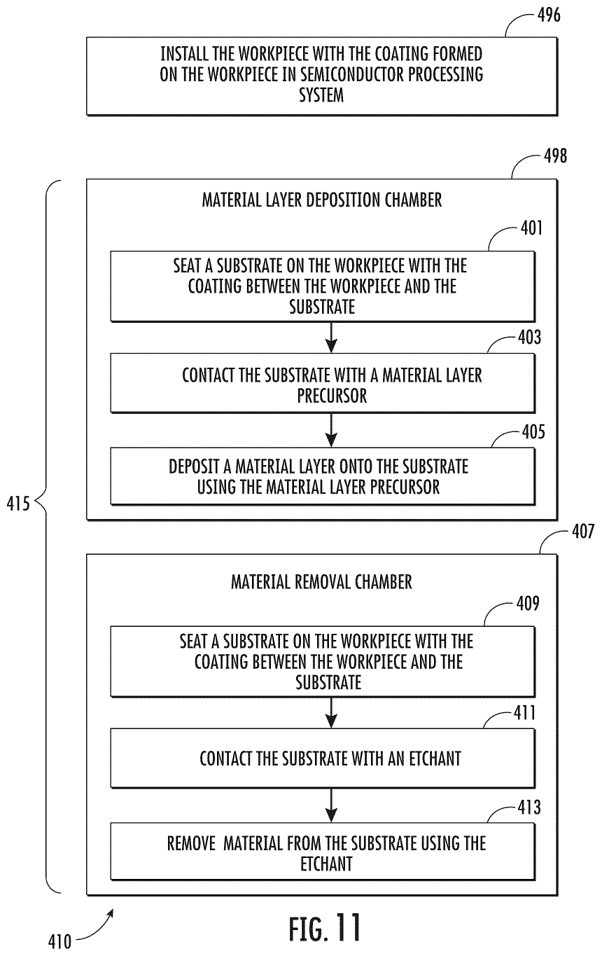

As shown in FIG. 11, installing 410 the workpiece with the coating formed thereon into the assembly or end item may include installing the workpiece in a semiconductor processing system, for example by orienting the substrate support body such that the seating portion of the substrate support body is above the stem portion of the substrate support body relative to gravity, as shown with box 496. In certain examples installing 410 the workpiece may include installing the workpiece with the coating formed thereon in a material layer deposition chamber, as shown with box 498. Once installed in the material layer deposition chamber, a substrate may be seated on the workpiece with the coating between the workpiece and the substrate, as shown with box 401; the substrate may be contacted with a material layer precursor, as shown with box 403; and a material layer deposited onto the substrate using the material layer precursor, as shown with box 405. In accordance with certain examples, installing 410 the workpiece with the coating formed thereon may include installing the workpiece with the coating formed thereon in a material removal chamber, as shown with box 407. Once installed in the material removal chamber a substrate may be seated on the workpiece such that the coating separates the substrate from the workpiece, as shown with box 409; the substrate may be contacted with an etchant, as shown with box 411; and material removed from the substrate using the etchant, as shown with box 413. It is also contemplated that, in certain examples, installing 410 the workpiece may include installing the workpiece in material layer deposition/material removal chamber, for example a chamber configured to perform a cyclic deposition and etch operation, as shown with bracket 415. In such examples material layers may be cyclically deposited and material thereafter removed, as shown with boxes 403-405 and 411-413.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A chamber arrangement, comprising:
an outer chamber with a hollow interior;
an inner chamber sized and dimensioned for placement within the interior of the outer chamber, the inner chamber configured to support therein a workpiece; and
an electrical connector seated in a wall of the outer chamber and fluidly separating the interior of the outer chamber from an external environment outside of the outer chamber, the electrical connector configured to provide electrical communication between the workpiece and a device located in the external environment outside of the chamber arrangement.

2. The chamber arrangement of claim 1, further comprising a lead arranged within the interior of the outer chamber and connected to the electrical connector.

3. The chamber arrangement of claim 1, wherein the electrical connector is one of a plurality of electrical connectors and seated in the wall of the outer chamber.

4. The chamber arrangement of claim 3, further comprising a lead arranged within the interior of the outer chamber and connected to the electrical connector to electrically couple the workpiece to the electrical connector.

5. The chamber arrangement of claim 4, wherein the lead is a first lead and the chamber arrangement further comprises a second lead to provide the electrical communication between the device located in the external environment outside of the chamber arrangement and the workpiece.

6. The chamber arrangement of claim 5, wherein the second lead is connected to the electrical connector.

7. The chamber arrangement of claim 5, wherein the electrical connector is a first electrical connector and the chamber arrangement further comprises a second electrical connector seated in the wall of the outer chamber, wherein the second lead is connected to the second electrical connector.

8. The chamber arrangement of claim 1, wherein the inner chamber comprises,
a base defining a recess configured to receive therein a seating portion of the workpiece;
a lid or cover seated on the base and defining therein one or more workpiece aperture, the one or more workpiece aperture configured to receive therethrough a stem portion of the workpiece extending from the seating portion of the workpiece; and
a collar having a first end and an opposite a second end, the first end seated on the lid or cover and extending about the one or more workpiece aperture, the second end spaced apart from the first end and configured to extend about and support the workpiece within the inner chamber such that the stem portion of the workpiece protrudes from the second end of the collar.

9. The chamber arrangement of claim 8, wherein the lid or cover of the inner chamber defines the one or more workpiece aperture, and wherein the outer chamber further comprises a conduit compressively fixed between the inner chamber and the wall of the outer chamber, the conduit configured to provide fluid communication with the recess defined within the base of the inner chamber.

10. The chamber arrangement of claim 9, wherein the one or more workpiece aperture is a first workpiece aperture and the conduit is a supply conduit, wherein the lid or cover defines a second workpiece aperture, and wherein the chamber arrangement further comprises an exhaust conduit compressively fixed between the inner chamber and the outer chamber.

11. The chamber arrangement of claim 10, further comprising:
a coating system precursor source fluidly coupled to the recess by the supply conduit; and
a coating system exhaust source fluidly coupled to the recess by the exhaust conduit.

12. The chamber arrangement of claim 9, wherein the conduit and the base of the inner chamber define a leakage path or gap therebetween, and wherein the interior of the outer chamber fluidly is coupled to the recess within the inner chamber by the leakage path or gap.

13. The chamber arrangement of claim 1, wherein the inner chamber is formed from stainless steel, aluminum, or titanium.

14. The chamber arrangement of claim 1, wherein the inner chamber is configured for coating a plurality of workpieces.

15. The chamber arrangement of claim 1, further comprising:
the workpiece supported at least partially within the inner chamber; and
a lead electrically connecting the workpiece to the electrical connector through the interior of the outer chamber.

16. The chamber arrangement of claim 15, wherein the workpiece comprises:
a substrate support body;
a heater element seated in the substrate support body;
a temperature sensor seated within the substrate support body; and
wherein at least one of the heater element and the temperature sensor is electrically connected to the electrical connector by the lead.

17. The chamber arrangement of claim 15, wherein the workpiece is a medical device, a battery structure, or a gas turbine engine structure.

18. The chamber arrangement of claim 16, further comprising a coating formed on the workpiece, wherein the coating is one of a thermal barrier coating, a diamond-like carbon coating, an etch resistant coating, and an emissivity-matching coating.

19. The chamber arrangement of claim 15, wherein the workpiece is formed from a stainless steel material, a nickel-based alloy, or an aluminum-containing, and wherein the workpiece is coated with a ceramic material.

20. A coating system, comprising:
a chamber comprising
an outer chamber with a hollow interior;
an inner chamber sized and dimensioned for placement within the interior of the outer chamber, the inner chamber configured to support therein a workpiece, inner chamber further including a base defining a recess therein, wherein the workpiece is partially supported within the recess of the inner chamber and protrudes from the inner chamber and into the interior of the outer chamber; and
an electrical connector seated in a wall of the outer chamber and fluidly separating the interior of the outer chamber from an external environment outside of the outer chamber, the electrical connector configured to provide electrical communication between the workpiece and a device located in the external environment outside of the chamber arrangement;
a coating system precursor source fluidly coupled to the inner chamber;
a coating system exhaust source fluidly coupled to the inner chamber and therethrough to the coating system precursor source through the recess defined within the inner chamber; and
a coating system controller operatively connected to the coating system precursor source and disposed in communication with the workpiece, the coating system controller responsive to instructions recorded on a memory to form a coating onto the workpiece.

21. A method of forming a coating, comprising:
at a chamber arrangement including an outer chamber with a hollow interior; an inner chamber sized and dimensioned for placement within the interior of the outer chamber, the inner chamber configured to support therein a workpiece; and an electrical connector seated in a wall of the outer chamber and fluidly separating the interior of the outer chamber from an external environment outside of the outer chamber, the electrical connector configured to provide electrical communication between the workpiece and a device located in the external environment outside of the chamber arrangement,
supporting the workpiece within the chamber arrangement;
forming a coating onto the workpiece while supported within the chamber arrangement;
removing the workpiece from the chamber arrangement; and
installing the workpiece with the coating formed thereon in an assembly or end item.
